(19) United States
(12) Patent Application Publication
(10) Pub. No.: US 2004/0151835 A1
(43) Pub. Date: Aug. 5, 2004

(54) Method for forming a coating film, consisting of carbon nanotubes, on the surface of a substrate

(76) Inventors: Mirko Croci, Avenches (CH); Jean-Marc Bonard, Lausanne (CH)

Correspondence Address: FOLEY AND LARDNER, SUITE 500, 3000 K STREET NW, WASHINGTON, DC, 20007, US

(21) Appl. No.: 10/468,145

(22) PCT Filed: Feb. 21, 2002
(86) PCT No.: PCT/CH02/00102

(30) Foreign Application Priority Data
Feb. 26, 2001 (CH) 342/01

(51) Int. Cl. C23C 16/26

(52) U.S. Cl. 427/249.1

(57) ABSTRACT

The invention concerns a method for forming a coating film, consisting of nanotubes, the surface of a substrate, which consists in contacting said surface with a gaseous atmosphere containing at least a carbon compound and causing thermal decomposition of said compound; therefor the part of the substrate surface which is to be coated is subjected to direct heating with means different from means possibly used for heating the gaseous atmosphere. Thus the nanotubes are grown perpendicularly to the surface of the substrate, with uniform spacing of their axes. An electron-emitting cathode, wherein the electron-emitting source consists of such a coating film, exhibits better emitting homogeneity as well as reduced operating voltage, compared to a cathode provided with a carbon nanotube coating film formed with a method in conformity with prior art.

The present invention has as its object a process for forming, on the surface of a substrate, a coating comprised of carbon nanotbues, whereby this surface is placed into contact with a gaseous atmosphere, containing at least one carbon compound, capable of forming a carbon nanotube structure from the surface of this substrate, and said surface is maintained at a temperature sufficient to allow for the desired extent of growth of the carbon nanotubes.

The use of carbon nanotubes, in other words, tubular filaments made of pure carbon, in the crystallized state in graphite form, with a length in the order of 1 to 100 micrometers and a diameter in the order of 0.01 to 0.1 micrometers (i.e. 10 to 100 nanometers), presents a growing advantage for the manufacture of electron-emitting sources appropriate for use in various scientific and industrial devices.

For example, such electron-emitting sources may be advantageously used, in place of thermoelectric emitters, in vacuum gauges, particularly of the Bayard-Alpert type or else in magnetic field detecting devices, ionizing elements for mass spectrometry, microwave amplifying devices, and photo-luminescent elements that use the conversion of ultraviolet light into visible light by means of a luminophore substance (photo-luminescent material), in which the UV light is obtained by electron bombardment of a gaseous atmosphere containing nitrogen or a nitrogen compound, in such a manner so as to cause the excitement of the nitrogen.

Recently it has come to light that it is particularly advantageous to use an electron-emitting source that includes a coating comprised of a plurality of carbon nanotubes, applied onto the surface of a substrate that is an electric conductor and adhering to this surface by forming a field-emitting film, like an electron-emitting cathode, functioning according to the known principle of cold electron emission (field emission by tunnel effect), for the manufacture of a luminescent lighting tube intended to replace the usual fluorescent tubes and presenting the advantage over the latter of making it possible to avoid using mercury in the internal atmosphere of the tube.

More precisely, a luminescent tube of this type includes, in addition to said electron source, a transparent or translucent enclosure, advantageously made of glass, preferably having a spherical or cylindrical shape, on the surface of which a layer of material that is electrically conductive is applied, for example, a metallic layer with a thickness that is sufficiently slight to ensure a proper transparency of this coating, which in turn is turn coated with a layer of electro-luminescent material having the property of emitting light under the effect of excitement by an electron beam. The substrate supporting the electron-emitting source is advantageously located in the center part of the enclosure, for example, in the axis of the tube, whenever the enclosure is constituted by a cylindrical tube.

For the purpose of obtaining a high density of electron emitters that constitute the field-emitting film, which is a condition necessary for uniform and intense radiation of the electro-luminescent material, it has recently been proposed that, on the surface of the substrate, the coating of carbon nanotubes be formed by high-temperature chemical decomposition in vapor phase of a gaseous atmosphere essentially composed of at least one appropriate compound containing carbon, such as carbon monoxide or a hydrocarbon.

According to such a process, the decomposition of a compound containing carbon or of a mixture of carbon compounds in the gaseous state is carried out in an appropriate reaction enclosure, for example, comprised of a quartz tube place inside a furnace that makes it possible to attain a high temperature, for example in the order of 700 to 800° C., which is necessary to cause this decomposition, and the growth of carbon nanotubes on the support surface placed inside the reaction enclosure. This support is advantageously comprised of a metal wire that has been previously coated with a material having a catalytic effect on the decomposition reactions of said compound and the growth of the carbon nanotubes.

Such a process makes it possible to create a high-quality field-emitting film; however it presents various drawbacks with respect to its use for the manufacture of a luminescent lighting tube.

In particular, in order to obtain a field-emitting film having uniform properties over the totality of its surface, it is necessary to subject the entire length of the support to heating that is likewise uniform. This involves the use of heating installations, such as tube furnaces, the cost of which increases depending on the length of the substrate and may become prohibitive in the case of the industrial manufacture of luminescent tubes having a length in the order of one meter.

Moreover, after the stage of the formation of the field-emitting film on the cathode, the cathode must be mounted in a position that is axial to the inside of the enclosure of the luminescent tube. To do this, it is necessary to ensure that there is a sound mechanical attachment and also adequate electrical contacts, for example by welding. These manipulations are difficult to carry out and involve a significant risk of damaging the electron-emitting structures and the layer of electro-luminescent material and, thereby, to detract from the uniformity and the stability of the electron emission and the light produced by the electro-luminescent material.

The present invention has as its object to remedy the drawbacks that have just been mentioned.

For this purpose, the process according to the invention is characterized in that the part of the surface destined to receive the coating is subjected to direct heating, by a means distinct from possible means of heating said gaseous atmosphere.

Thus the process according to the invention presents the advantage of allowing for the manufacture of the electron-emitting cathode for a luminescent tube by carrying out the deposit of the carbon nanotube coating that constitutes the field-emitting film, on the surface of substrate, after this substrate has been completely assembled in the enclosure of the luminescent tube, the wall of which is already provided, on its inside surface, with the layer of electro-luminescent material, right before the final sealing of the tube and before it is placed under vacuum.

The result is that this process is perfectly suited to the industrial manufacture of fluorescent tubes.

In addition, quite unexpectedly, the process according to the invention presents, in relation to the previously known process, mentioned above, whereby the gaseous reaction atmosphere, as a whole, is raised to the temperature allowing for the decomposition of the carbon compound and the growth of the carbon nanotubes by means of heating such as a tube furnace, presents the advantage that the carbon nanotubes grow with their axes oriented perpendicularly to the surface of the substrate, which provides them with a very high degree of alignment as well as regular spacing, while the nanotubes obtained by prior process grow in essentially random directions.

The difference in structure thus obtained translates into attaining a significant improvement in the homogeneity of the electron emission as well as a lowering in the operating voltage for an electron-emitting cathode obtained by the process according to the invention in comparison to a cathode obtained by the prior process. It can be understood that the invention thus allows for a significant improvement in the quality of a luminescent tube equipped with such a cathode.

As a constitutive material for the substrate, it may be advantageous to use any metallic material (for example molybdenum, iron, nickel or even alloys of these elements among themselves or with other elements, particularly steel, a nickel-chrome alloy, an alloy of iron, aluminum and chrome, such as that which is marketed under the name “Kanthal”), or else a semi-conductor material (for example, highly doped silicon). In addition, it may also be possible to use a special glass that is an electric conductor.

The substrate may have any shape appropriate to the intended use for the electron-emitting cathode. For example, the substrate may be flat, particular in the form of a small plate, or else non-plane, particularly in the form of a wire, a bar, a sphere or a semi-sphere. Although, a rectilinear substrate is preferably used, the substrate may likewise be formed as a spiral or constitute a reel, or it may be constituted as a mechanical piece, such as a screw.

Advantageously, the surface of the substrate is coated, prior to the formation of the carbon nanotube coating, with one or more layers of at least one substance having a catalytic effect on the decomposition of the carbon compound and/or the growth of the carbon nanotubes.

Such a catalytic substance may, for example, consist of an iron salt, nickel or cobalt (for example, one of the following salts: Fe(NO₃)₃.9H₂O; Ni(NO₃)₂.6H₂O; Co(NO₃)₂.6H₂O) or a mixture of such salts. In particular, it is possible to use a solution of such salts or mixtures of salts in an appropriate solvent, such as ethanol, for example, with a solution having a salt concentration in the order of 50 mM. Whenever such a catalytic substance is used, the application of the catalytic substance onto the surface of the substrate may be done by simple short-duration immersion of the substrate in a bath of solution or else by the impression of this surface by means of a plastic pad or by nebulizing. Thus it is possible to obtain a catalyst film that can be continuous over the entire surface of the substrate or else be structured in the form of separate areas in order to allow for the selective growth of the carbon nanotubes on only one part of this surface.

Beyond the use, mentioned above, of a catalyst solution, it is possible to carry out an application of catalyst on the surface of the substrate of any other appropriate material, in particularly using a depositing method known as “electro-less,” evaporation by electron beam, cathode pulverization, etc.

As a variant, the catalytic substance may not be necessary or it may be contained in the very material of the substrate itself; this, for example, is the case whenever the substrate is a transition metal, such as iron, nickel or cobalt, or alloy containing such a metal. In particular, the use of nickel-chrome alloy with the formula Ni₈₀ Cr₂₀ makes it possible to obtain a catalytic effect of the substrate itself.

In order to obtain an improvement in the result of the application of the catalytic material onto the substrate, for example better adherence of the deposited material to the surface of the substrate, it may be advantageous to subject this surface to a preparatory treatment prior to this application. Thus, for example, such a surface treatment may be carried out by oxidation of this surface in the air or in oxygen at a temperature above 150° C., or else by heating in a reducing atmosphere, likewise preferably done at a temperature above 150° C., or by any other appropriate technique, such as treatment in an electric plasma, etching or any other kind of surface treatment, particularly by means of an acid or a base, or else an electro-polishing treatment.

It is also possible to deposit, onto the surface of the support, before the application of the catalyst, a layer of material that will enhance the adhesion of the catalyst, for example, a layer of titanium.

Before the actual operation of forming the carbon nanotube coating on the substrate, it may be advantageous to subject the substrate to a treatment intended to improve the adhesiveness of the coating to the substrate. Such a treatment can, for example, consist in annealing under vacuum or else under a gas stream, such as nitrogen, hydrogen, oxygen, ammonium or even a mixture of gases, particularly a mixture of hydrogen and nitrogen.

As a carbon compound that can be decomposed, giving rise to the formation of the carbon nanotubes, it may be advantageous to use, for example, carbon monoxide or else a hydrocarbon such as acetylene, methane, ethylene, butane, benzene, or a mixture of such compounds. It may be advantageous to use a diluting gas such as hydrogen, ammonium or nitrogen.

The pressure at which this operation is carried out advantageously ranges between 10⁻⁵ and 10.10³ millibars, preferably between 10⁻³ and 200 millibars.

The growth of the nanotubes may be carried out under gas stream or under a static atmosphere.

Advantageously, the temperature of the substrate is maintained in the range between 300° C. and 1,500° C., during the formation of the nanotubes.

To heat the substrate, it is possible to proceed in any appropriate manner. Preferably, the heating is done by Joule effect, by passing an electric current through the constitutive material of the substrate itself. However, it is also possible to use a heating substrate support or even a heating filament placed in contact with the substrate or in the vicinity of the substrate or else placed in the mass of the substrate.

After the formation and growth of the nanotubes, it may be advantageous to carry out a treatment that will make it possible to improve the properties of the coating, particularly increasing the adhesiveness of the nanotubes to the surface of the substrate. Such a treatment may, for example, consisting of annealing, under a vacuum or in the air, or in an atmosphere formed by another gas or by an appropriate gaseous mixture, of the substrate, coated by the carbon nanotube coating. Advantageously, the lower limit of the temperature range appropriate for such a treatment is in the order of 150° C.

Now follows a detailed description of the implementation of the process according to the invention, as a non-limiting example, with references to the attached drawing, in which:

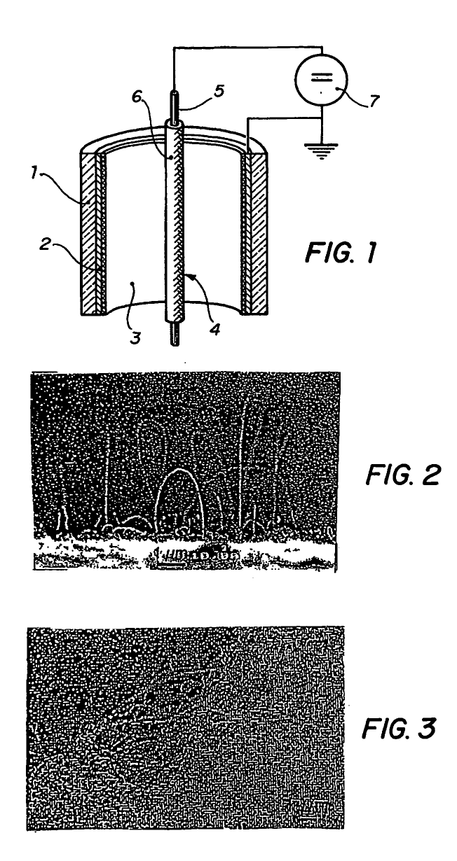

FIG. 1 is a diagrammatic view, in exploded perspective, with one part in a cutaway view, of one part of a luminescent tube equipped with a field emission electron-emitting cathode;

FIG. 2 represents an electron scanning microscopy micrograph, showing the structure of a carbon nanotube coating obtained by the process according to the invention.

FIG. 3 represents an electron scanning microscopy micrograph, showing the structure of a carbon nanotube coating obtained by a chemical decomposition process at high temperature according to prior art;

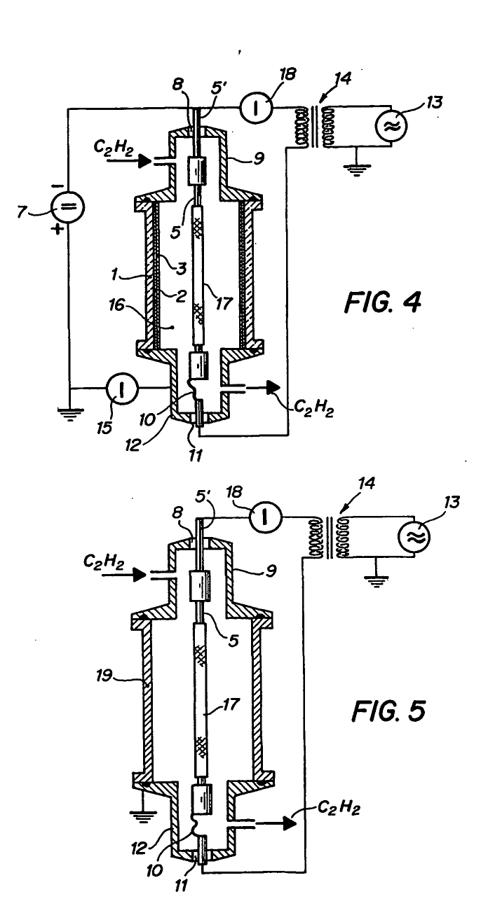

FIG. 4 is a diagrammatic cross-section of an experimental device for the formation of a carbon nanotube coating using the process according to the invention, according to a first embodiment of this process;

FIG. 5 is a diagrammatic cross-section of an experimental device for the formation of a carbon nanotube coating using the process according to the invention, according to a second embodiment of this process; and

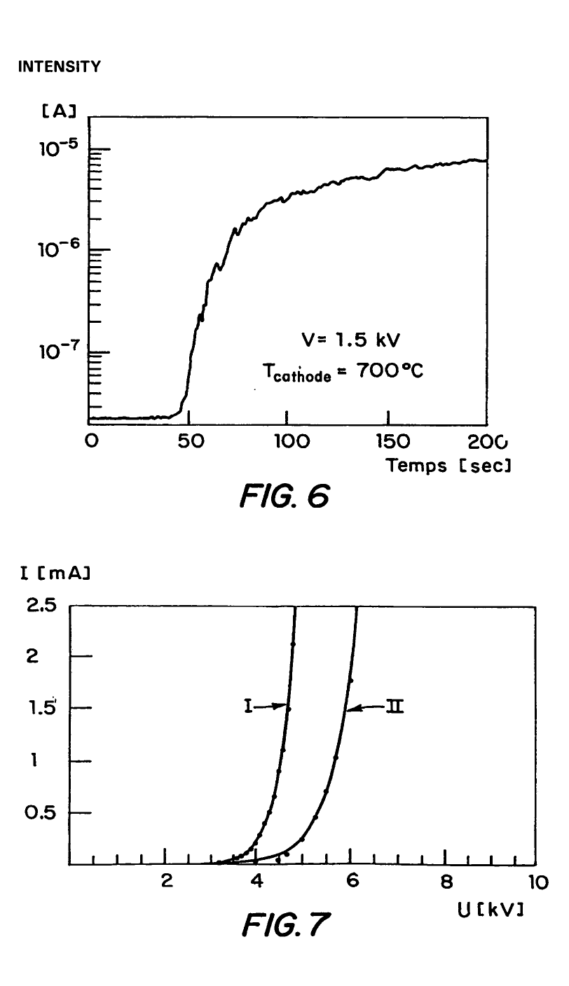

FIG. 6 is a diagram showing a curve characteristic of the variation in the intensity of the field emission current measured during the growth of the carbon nanotubes, during the implementation of the process according to the invention, according to the embodiment using the device illustrated in FIG. 5.

FIG. 7 is a diagram showing the curves characteristic of the variation in the intensity of the field emission current, depending on the difference in the potential applied between the cathode and the anode, in a luminescent tube comprising a cathode manufactured by applying a process for the formation of a carbon nanotube coating, according to the invention and according to prior art, respectively.

The luminescent tube, partially represented in FIG. 1, comprises a cylindrical tube 1, made of glass, the inside of which delimits an enclosure under a vacuum. Tube 1 is hermetically closed at both its extremities (not represented) in such a way to make it possible to maintain the inside of the enclosure under a sufficiently high vacuum, in order of 10⁻⁶ millibars, for the functioning of the luminescent tube. The inside wall of tube 1 is coated with a transparent layer 2 of a material that is an electric conductor, such as indium oxide and tin oxide (designated by the name “ITO” or “ATO”), which is itself coated with a layer 3 of electro-luminescent material, such as the product designated by the commercial name “Lumilux B 45” of the Riedel de Haehn company, with the composition Y₂O₂S:Tb.

A field effect electron-emitting cathode 4, comprised of a metal wire 5, for example a wire made of “Kanthal,” 0.3 mm in diameter, coated over its entire surface by a layer 6 of carbon nanotubes, is placed in the center of tube 1, parallel to the axis of the tube.

A high voltage continuous current source 7, for example 1.5 kV, is connected between the metal wire 5 of cathode 4 and layer 2 of conductive material in such a manner so as to make it possible to cause the emission of electrons by cathode 4, in order to produce the emission of visible light by excitement of layer 3 of electro-luminescent material.

As can be seen in FIG. 2, the carbon nanotubes, obtained by the process according to the invention, have a high degree of alignment, resulting from their growth essentially in the direction that is perpendicular to the surface of the substrate, as well as a regular spacing.

In comparison, the carbon nanotubes obtained by the vapor phase chemical deposit process, from a gaseous atmosphere at high temperature, have directions of growth oriented in a random manner, as can be clearly seen from FIG. 3.

These differences in the structure of the coatings obtained by the process according to the invention (FIG. 2) and by the process according to prior art (FIG. 3), respectively, show the attainment of a clear improvement in the functioning characteristics and in the quality of the luminous emission of a luminescent tube in which the electron-emitting cathode is equipped with a carbon nanotube coating obtained using the process according to the invention.

More precisely, the use of such a coating makes possible a significant decrease in the operating voltage of the tube, while ensuring a greater homogeneity and a greater density of the emission of electrons by the cathodes, likewise resulting in a better homogeneity in the luminous emission by the layer of luminescent material.

Now follow some non-limiting examples illustrating the implementation of the process:

### EXAMPLE 1

The device, represented in FIG. 4, including a cylindrical tube, made of glass, having a diameter of 42 mm and a wall thickness of 3 mm arranged vertically, and the upper and lower extremities are, respectively, closed by a vacuum shield 9 and a vacuum shield 12, thus constituting a vacuum enclosure 16.

A “Kanthal” wire 5, 0.3 mm in diameter, constituting the substrate destined to be covered by a carbon nanotube coating, is mounted in the center of the tube 1 parallel to the axis of that tube. The upper extremity 5′ of wire 5 is attached on a first hermetically sealed electric duct 8 crossing the end wall of vacuum shield 9, and the lower end of wire 5 is connected with a flexible copper strand 10, connected to a second hermetically sealed electric duct 11 crossing the end wall of vacuum shield 12.

Prior to the mounting of wire 5 in tube 1, the surface is cleaned with acetone, then with methanol and finally with ethanol, and it is heated to 1000° C., in an air atmosphere, in a furnace, for 12 hours, in such a way so as form a protective layer on the surface of the wire.

Then the wire is allowed to cool to room temperature and it is soaked for 3 seconds in a solution of iron nitrate Fe(NO₃)₃.9H₂O, in ethanol having a concentration of 50 mM per liter, then the wire is taken out of this solution and is dried under a stream of nitrogen. This operation makes it possible to deposit onto the surface of the wire a layer of iron nitrate that has a catalytic effect on the thermal decomposition of the carbon compound for the formation of carbon nanotubes on the surface of the wire. As in the case of the luminescent tube represented in FIG. 1, the inner wall of tube 1 is coated with a first transparent layer 2 of indium oxide and tin oxide, which is in turn covered by a second layer 3 of electro-luminescent material.

A source 13 of alternating electric current, connected to the primary circuit of a transformer 14, of which one terminal of the secondary current is connected to the electric duct 8 and the other to the electric duct 11, makes it possible to heat wire 5 by the Joule effect. Ammeter 18 makes it possible to measure the intensity of the heating current of wire 5.

A source 7 of high voltage continuous current, as in the case of the luminescent tube in FIG. 1, is connected between wire 5 and layer 3 of electro-luminescent material covering the inner wall of tube 1. More precisely, the negative terminal of source 7 is directly connected to electric duct 8 and its positive terminal is connected to shield 12 by way of ammeter 15, which thus allows for the measurement of the intensity of the field emission current during the formation of the carbon nanotubes on the surface of wire 5.

To form a carbon nanotube coating on the surface of wire 5, while measuring the intensity of the field emission current as the nanotubes grow, a vacuum in the order of 10⁻⁶ mbar is established inside tube 1 and then a continuous voltage of 1.5 kV is applied between wire 5 and the layer of electro-luminescent material 3. After this, wire 5 is heated to 720° C., by the Joule effect by allowing an alternating current with an intensity of approximately 1 ampere to pass through it. After a period of 5 minutes of heating at 720° C. in the 10⁻⁶ mbar vacuum, an acetylene stream is introduced into tube 1 and the partial pressure of the acetylene is adjusted to a value of 10⁻³ mbar. After a period of approximately 50 seconds, the start of a field emission is detected, measured by means of ammeter 15, as well as the appearance of luminous spots on the layer of electro-luminescent material 3.

This field emission current results from the formation of a coating 17 of carbon nanotubes on the surface of wire 5, thus constituting an electron-emitting cathode. The electron flow emitted by this cathode causes the excitement of the layer of electro-luminescent material 3. As represented in FIG. 6, the field emission current increases rapidly, depending on the time that wire 5 is exposed to the acetylene atmosphere. It can be seen that the intensity of the field emission current reaches a step value in the order of 10⁻⁵ amperes at the end of 150 to 200 seconds approximately.

Parallel to this increase in the intensity of the field emission current, which reflects the growth of the carbon nanotubes, the luminous spots increase in number until they occupy the entire surface of layer 3. This indicates that the growth of the carbon nanotube coating has attained a sufficient degree of advancement.

At that moment, the growth of the carbon nanotubes is stopped by interrupting the supply of acetylene and a vacuum in the order of 10-6 mbar is established inside tube 1.

The temperature of the wire 5 is maintained at 720° C. is maintained for about 15 minutes after the end of the operation of forming the carbon nanotube coating on wire 5 in order to increase the homogeneity of this coating.

### EXAMPLE 2

The procedure is similar to that described in example 1, again using the device represented in FIG. 4, but, instead of performing the measurement of the intensity of the field emission current during the formation of the carbon nanotube coating on the surface of wire 5, this measurement is carried out in the course of an operational phase distinct from the formation of this coating.

More precisely, the carbon nanotube coating 17 is formed in the course of an operational phase carried out without any application of continuous voltage between wire 5 and the layer of electro-luminescent material 3. This makes it possible to adjust the partial pressure of the acetylene at 200 mbar, instead of 10⁻³ mbar, and thus to obtain, for a given duration for the growth of the nanotubes, a coating that has a higher density of tubes than that which is obtained under the conditions indicated in example 1.

The process of the growth of the carbon nanotubes is interrupted by evacuating the acetylene, at the end of a period during which coating 17 is formed lasting 30 seconds, and a 10⁻⁶ mbar vacuum is established inside the enclosure.

After this, a continuous voltage of 5 kV is applied between wire 5 and the layer of electro-luminescent material 3 and the light intensity emanating from the outer surface of tube 1 is measured.

If necessary, there follows a series of alternating operations for forming the carbon nanotube coating and for measuring the field emission current, by repeating the two operational phases that have just been described, until an electron-emitting cathode is obtained, which makes it possible to obtain a sufficient intensity of field emission current and a sufficient density of electron emitters, corresponding, for example, to the values of 1 mA and 5 emitters per square centimeter of surface, respectively, on the layer of electro-luminescent material 3.

### EXAMPLE 3

The device, represented in FIG. 5, similar to that of FIG. 4, is used; however, in it, the cylindrical tube 1 made of glass is replaced by a cylindrical tube 19 made of aluminum, with the same diameter and thickness as tube 1, while its inner wall does not have a layer of coating.

Moreover, the device in FIG. 5 does not include the circuit to supply high voltage continuous current.

By means of this device, a carbon nanotube coating is formed on the surface of a Kanthal wire, following a procedure analogous to the one described in examples 1 and 2, under a partial pressure of acetylene of 200 mbar, while wire 5 is heated to 720° C. by the Joule effect, by causing an alternating current of 1 ampere to pass, for a single period of growth for the carbon nanotubes, lasting 30 minutes.

As can be seen in FIG. 7, an electron-emitting cathode by field effect, obtained by forming a carbon nanotube coating on the surface of the Kanthal wire, using the process according to the invention, in the manner described in example 2, with a total duration of 3 minutes for the growth of the carbon nanotubes, makes it possible to obtain an intensity of field emission current corresponding to curve I of the diagram of the variation in the intensity, depending on the continuous voltage applied between the emitting cathode and the anode, which is clearly greater than that obtained in the case of a cathode obtained by forming carbon nanotube coating using the process according to prior art (by carrying out the decomposition of an atmosphere composed of 80% nitrogen and 20% acetylene by volume, under a pressure of 1 bar, heated to 720° C. in a furnace on contact with a Kanthal wire lacking means of heating), corresponding to curve II of the diagram of FIG. 7.

1. Process for forming, on the surface of a substrate, a coating composed of carbon nanotubes, whereby this surface is placed into contact with a gaseous atmosphere, containing at least one carbon compound, and capable of forming of a carbon nanotube structure, by means of thermal decomposition upon contact with said substrate, and growth of carbon nanotubes from the surface of that substrate, and said surface is maintained at a temperature appropriate for said thermal decomposition for a sufficient time to allow for a desired extent of growth of carbon nanotubes, characterized in that the part of the surface destined to receive the coating is subjected to direct heating by a means distinct from possible means of heating said gaseous atmosphere.

2. Process according to claim 1, characterized in that said substrate is at least partially comprised of a material that is an electric conductor and that the heating of the surface of the substrate destined to receive the carbon nanotube coating is carried out by the Joule effect.

3. Process according to claim 2, characterized in that the substrate is composed of an alloy of iron, aluminum and chrome.

4. Process according to one of claims 1 to 3, characterized in that the substrate is in the form of a wire.

5. Process according to claim 1, characterized in that said carbon compound is chosen from among carbon monoxide, the hydrocarbons and the mixtures of at least two of these compounds.

6. Process according to claim 5, characterized in that, as a carbon compound, at least one hydrocarbon is used, chosen from among acetylene, methane, ethylene, butane and benzene.

7. Process according to one of claims 1 to 6, characterized in that the surface of the substrate is coated, prior to the formation of the carbon nanotube coating, with at least one layer of a substance having a catalytic effect on the decomposition of said carbon compound and/or the growth of the carbon nanotubes.

8. Process according to one of claims 1 to 6, characterized in that the material that constitutes the substrate has a catalytic effect on the decomposition of said carbon compound and/or the growth of the carbon nanotubes.

9. Process according to one of claims 1 to 8, characterized in that the surface of the substrate, prior to the formation of the carbon nanotube coating, is subjected to a treatment intended to enhance the adhesiveness of the coating on the substrate.

10. Process according to claim 9, characterized in that said treatment consists in annealing in a vacuum or under a gas stream.

11. Process according to one of claims 1 to 10, characterized in that the surface of the substrate is maintained at a temperature ranging between 300° C. and 1,500° C., during the thermal decomposition of said carbon compound.

12. Process according to one of claims 1 to 11, characterized in that said gaseous atmosphere is maintained under pressure ranging between 10⁻⁵ and 10.10³ millibars, during the thermal decomposition of said carbon compound.

13. Application of the process according to claim 1 to manufacture an electron-emitting source.

14. Electron-emitting cathode obtained by the application of the process according to claim 1.

15. Luminescent tube including a cathode according to claim 14.
